(19) United States
(12) Patent Application Publication
(10) Pub. No.: US 2023/0253223 A1
(43) Pub. Date: Aug. 10, 2023

(54) SUBSTRATE PROCESSING APPARATUS AND METHOD FOR CORRECTING POSITIONAL DISPLACEMENT

(71) Applicant: TOKYO ELECTRON LIMITED, Tokyo (JP)

(72) Inventor: Tamihiro KOBAYASHI, Tokyo (JP)

(21) Appl. No.: 18/102,279

(22) Filed: Jan. 27, 2023

(30) Foreign Application Priority Data
Feb. 7, 2022 (JP) 2022-016892

(51) Int. Cl. H01L 21/67; H01L 21/66

(52) U.S. Cl. CPC H01L 21/67259; H01L 22/12; H01L 21/67248

(57) ABSTRACT

There is provided a substrate processing apparatus. The apparatus comprises: a processing chamber; an attaching plate attached to the processing chamber while being positioned by a first positioning mechanism in a direction in which the processing chamber extends and contracts due to expansion and contraction caused by temperature changes with respect to a predetermined reference position serving as a reference for measuring positional displacement in the processing chamber; and a placing table configured to place a substrate thereon and disposed in the processing chamber via a support mechanism attached to the attaching plate, the support mechanism being positioned by a second positioning mechanism at a position opposite to a position of the first positioning mechanism with respect to the reference position.

### CROSS-REFERENCE TO RELATED APPLICATIONS

This application claims priority to Japanese Patent Application No. 2022-016892 filed on Feb. 7, 2022, the entire contents of which are incorporated herein by reference.

### TECHNICAL FIELD

The present disclosure relates to a substrate processing apparatus and a method for correcting positional displacement.

### BACKGROUND

As an example of a positioning method, Patent Document 1 discloses a method of positioning a focus ring and a placing table, by providing a recess(es) on a back surface of the focus ring and inserting a positioning pin(s) protruding from a surface of the placing table that faces the focus ring into the recess(es).

### SUMMARY

The present disclosure provides a technique for suppressing positional displacement.

In accordance with an aspect of the present disclosure, there is provided a substrate processing apparatus comprising: a processing chamber; an attaching plate attached to the processing chamber while being positioned by a first positioning mechanism in a direction in which the processing chamber extends and contracts due to expansion and contraction caused by temperature changes with respect to a predetermined reference position serving as a reference for measuring positional displacement in the processing chamber; and a placing table configured to place a substrate thereon and disposed in the processing chamber via a support mechanism attached to the attaching plate, the support mechanism being positioned by a second positioning mechanism at a position opposite to a position of the first positioning mechanism with respect to the reference position.

### BRIEF DESCRIPTION OF THE DRAWINGS

The objects and features of the present disclosure will become apparent from the following description of embodiments, given in conjunction with the accompanying drawings, in which:

FIG. 1 is a diagram showing an example of a schematic configuration of a substrate processing apparatus according to a first embodiment;

FIG. 2 is a diagram showing an example of attaching positions of an attaching plate and a support mechanism according to the first embodiment;

FIG. 3 is a diagram for explaining movement of the attaching plate and the support mechanism of the substrate processing apparatus according to the first embodiment;

FIG. 4 is a diagram showing an example of a schematic configuration of a substrate processing apparatus according to a comparative example;

FIG. 5 is a diagram for explaining movement of the attaching plate and the support mechanism of the substrate processing apparatus according to the comparative example;

FIG. 6 is a diagram showing an example of a schematic configuration of a substrate processing apparatus according to a second embodiment; and

FIG. 7 is a flowchart showing an example of a flow of a method for correcting positional displacement according to the second embodiment.

### DETAILED DESCRIPTION

Hereinafter, embodiments of a substrate processing apparatus and a method for correcting positional displacement disclosed in the present application will be described in detail with reference to the drawings. It should be noted that the disclosed substrate processing apparatus and method for correcting positional displacement are not limited by the present embodiments.

There is known a substrate processing apparatus for performing substrate processing by reducing a pressure in a chamber in which a substrate is placed. In the substrate processing apparatus, constituent members such as a placing table on which a substrate is placed are provided in the chamber, and the constituent members may be displaced due to expansion, contraction, or the like due to temperature changes in the chamber. In the substrate processing apparatus, when the constituent member is displaced, the processing results of the substrate processing on the substrate may not be uniform.

Therefore, a technique for suppressing positional displacement is expected.

### First Embodiment

### Configuration of Substrate Processing Apparatus

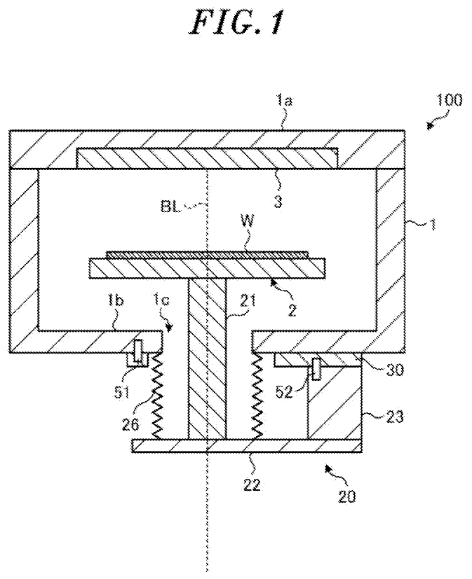

An embodiment will be described. First, a substrate processing apparatus 100 according to a first embodiment will be described. FIG. 1 is a diagram showing an example of a schematic configuration of the substrate processing apparatus 100 according to the first embodiment. The substrate processing apparatus 100 is an apparatus that performs substrate processing on a substrate. In the embodiment, a case, where the substrate processing apparatus 100 is used as a plasma processing apparatus and plasma processing such as plasma CVD or plasma etching is performed as substrate processing on the substrate, will be described as an example.

The substrate processing apparatus 100 has a chamber 1. The chamber 1 is made of metal such as aluminum and has a substantially cylindrical shape. A placing table 2 on which a substrate W such as a semiconductor wafer is placed is provided in the chamber 1. The chamber 1 is provided with a shower plate 3 above the placing table 2.

The shower plate 3 is provided so as to face the placing table 2. The shower plate 3 is fixed to a ceiling wall 1a forming the ceiling of the chamber 1. The chamber 1 is evacuated by an exhaust mechanism (not shown) and the inside of the chamber is depressurized to a predetermined depressurized state. The shower plate 3 is supplied with various gases used for substrate processing from a gas supply (not shown) and ejects the supplied gases into the chamber 1. Either or both of the placing table 2 and the shower plate 3 are supplied with high-frequency power from a high-frequency power supply. In the chamber 1, high-frequency power is supplied to one or both of the placing table 2 and the shower plate 3, whereby a high-frequency electric field is formed inside and the gases ejected from the shower plate 3 are turned into plasma.

The upper surface of the placing table 2 is formed in a disc shape having a diameter larger than that of the substrate W. The placing table 2 supports the substrate W placed on the upper surface of the placing table. The placing table 2 is supported by a support mechanism 20 so as to be able to be raised and lowered, and is disposed in the chamber 1 via the support mechanism 20. The support mechanism 20 includes a support member 21, a plate 22, and a raising and lowering mechanism 23.

The chamber 1 has an opening 1c formed in a bottom wall 1b. The support member 21 extends downward from the chamber 1 through the opening 1c formed in the bottom wall 1b of the chamber 1 from the center of the bottom surface of the placing table 2. A lower end of the support member 21 is fixed to the plate 22. The plate 22 is fixed to the raising and lowering mechanism 23.

The raising and lowering mechanism 23 supports the placing table 2 via the support member 21 and the plate 22. The placing table 2 is disposed in the chamber 1 via the support mechanism 20. The raising and lowering mechanism 23 raises and lowers the support member 21 and the plate 22. As the support member 21 and the plate 22 are raised and lowered by the raising and lowering mechanism 23, the placing table 2 is raised and lowered between an upper processing position in the chamber 1 where the substrate processing is performed and a lower transfer position in the chamber 1 where the substrate W can be transferred. A bellows 26 is provided between the bottom surface of the chamber 1 and the plate 22 so as to surround the support member 21. The bellows 26 expands and contracts as the placing table 2 is raised and lowered. The bellows 26 separates the atmosphere inside the chamber 1 from the outside air, and maintains the inside of the chamber 1 in a depressurized state when the placing table 2 is raised and lowered as well.

An attaching plate 30 is attached to the chamber 1 while being positioned by a first positioning mechanism. For example, the attaching plate 30 is attached to the bottom wall 1b of the chamber 1 while being positioned by a positioning pin 51. The support mechanism 20 is attached to the attaching plate 30 while being positioned by a second positioning mechanism. For example, the support mechanism 20 is attached to the attaching plate 30 while being positioned by a positioning pin 52. The attaching plate 30 is an example of an attaching member, the positioning pin 51 is an example of the first positioning mechanism, and the positioning pin 52 is an example of the second positioning mechanism.

In the substrate processing apparatus 100, positional displacement of constituent members may occur due to expansion, contraction, or the like caused by temperature changes in the chamber 1. For example, in the substrate processing apparatus 100, the positional displacement of the placing table 2 occurs due to expansion and contraction caused by temperature changes in the chamber 1. In the substrate processing apparatus 100, when the positional displacement of the placing table 2 occurs, the processing results of the substrate processing on the substrate W may not be uniform.

Therefore, in the substrate processing apparatus 100 according to the present embodiment, the attaching plate 30 is attached while being positioned by the positioning pin 51 in a direction in which the chamber 1 extends and contracts due to expansion and contraction caused by temperature changes with respect to a predetermined reference position that serves as a reference for measuring positional displacement in the chamber 1.

The reference position is a position that serves as the reference for measuring positional displacement of the constituent members installed in the chamber 1. In the present embodiment, the reference position is indicated by a line BL. The reference position BL is the central position in the chamber 1 along the vertical direction. In the substrate processing apparatus 100, the center of the placing table 2 is aligned with the center of the chamber 1 in order to improve in-plane uniformity and symmetry of the substrate processing on the substrate W. For example, the reference position BL is the central position of the shower plate 3. The placing table 2 is disposed so that the center of the placing table 2 is aligned with the center of the shower plate 3.

Further, in the substrate processing apparatus 100 according to the present embodiment, the support mechanism 20 is attached to the attaching plate 30 while being positioned by the positioning pin 52 at a position opposite to the position of the positioning pin 51 with respect to the reference position BL. The placing table 2 is disposed in the chamber 1 via the support mechanism 20 attached to the attaching plate 30.

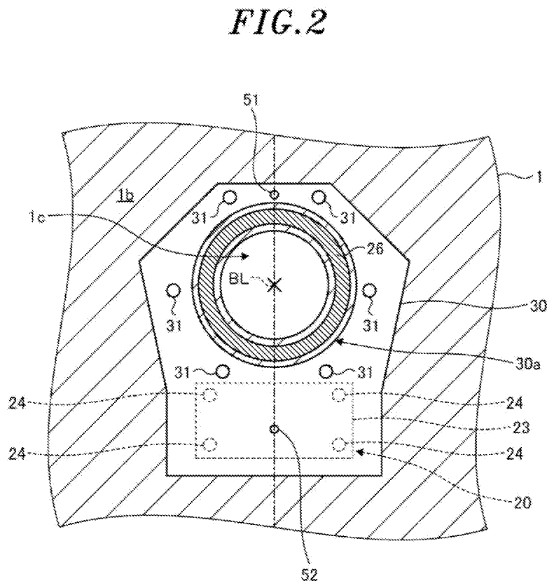

FIG. 2 is a diagram showing an example of attaching positions of the attaching plate 30 and the support mechanism 20 according to the first embodiment. FIG. 2 shows the bottom wall 1b of the chamber 1 viewed from below. The bottom wall 1b of the chamber 1 is formed with the opening 1c. The opening 1c is formed in a circular shape centered on the reference position BL. FIG. 2 shows the reference position BL at the center of the opening 1c.

The attaching plate 30 is attached so as to surround the opening 1c in the bottom wall 1b of the chamber 1. In the present embodiment, the attaching plate 30 is formed with a circular opening 30a that is larger than the opening 1c in the bottom wall 1b of the chamber 1. The attaching plate 30 is attached so that the opening 1c is positioned within the opening 30a.

The attaching plate 30 is positioned on the bottom wall 1b of the chamber 1 by the positioning pin 51, and is attached to the bottom wall 1b of the chamber 1 at a plurality of locations around the opening 1c by attaching bolts. FIG. 2 shows the arrangement position of the positioning pin 51 above the opening 1c, and the arrangement positions of the attaching bolts for attaching the attaching plate 30 around the opening 1c.

The support mechanism 20 is attached to the attaching plate 30 while being positioned by the positioning pin 52 at a position opposite to the position of the positioning pin 51 with respect to the reference position BL. In the present embodiment, the raising and lowering mechanism 23 of the support mechanism 20 is positioned on the attaching plate 30 by the positioning pin 52 at a position opposite to the position of the positioning pin 51 with respect to the reference position BL, and is attached to the attaching plate 30 at a plurality of locations by attaching bolts. FIG. 2 shows the arrangement position of the positioning pin 52 below the opening 1c, and the arrangement positions 24 of the attaching bolts for attaching the raising and lowering mechanism 23. The reference position BL, the position of the positioning pin 51, and the position of the positioning pin 52 are arranged in a straight line shape (on a straight line in plan view). The positioning pins 51 and 52 are in a state where there is no gap around them. The attaching bolts at the arrangement positions 31 and the arrangement positions 24 have a slight gap around them.

By the way, in the substrate processing apparatus 100, the temperature of the chamber 1 is raised and adjusted to a temperature suitable for substrate processing, so that the chamber 1 is expanded. Further, when the substrate processing is performed in the chamber 1, the chamber 1 may be expanded or contracted due to temperature changes caused by heat generated by the substrate processing. For example, when the substrate processing apparatus 100 performs plasma processing such as plasma CVD and plasma etching in the chamber 1, the chamber 1 is expanded by heat input from the plasma. As a result, the positions of the attaching plate 30 and the raising and lowering mechanism 23 are moved.

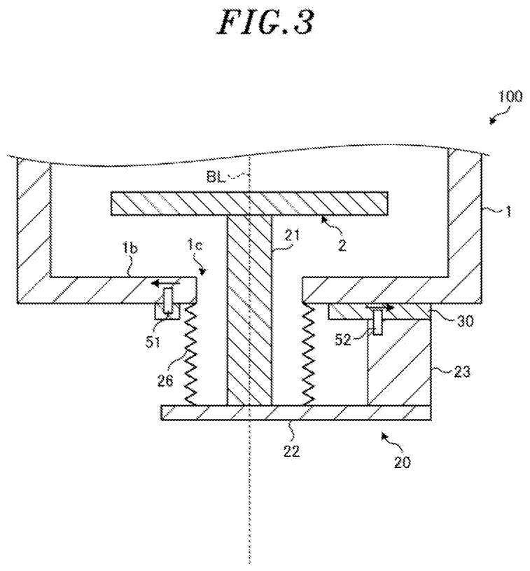

FIG. 3 is a diagram for explaining movement of the attaching plate 30 and the support mechanism 20 of the substrate processing apparatus 100 according to the first embodiment. The bottom wall 1b extends by expansion of the chamber 1. For example, the bottom wall 1b of the chamber 1 extends to the left and the right in FIG. 3 with respect to the reference position BL. As a result, the positioning pin 51 in the bottom wall 1b of the chamber 1 moves to the left. Although the attaching plate 30 is held against the bottom wall 1b by the attaching bolts, it is slightly movable. Since the attaching plate 30 is positioned on the bottom wall 1b by the positioning pin 51, the attaching plate 30 is pulled to the left and moves to the left as a whole.

The attaching plate 30 expands and extends due to heat transfer from the bottom wall 1b. For example, as shown in FIG. 3, since the attaching plate 30 is positioned on the bottom wall 1b by the positioning pin 51, it extends mainly to the right due to the expansion. As a result, the positioning pin 52 in the attaching plate 30 moves to the right with respect to the reference position BL. Since the support mechanism 20 is positioned on the attaching plate 30 by the positioning pin 52, the support mechanism 20 is pulled to the right and moves to the right as a whole.

The placing table 2 supported by the support mechanism 20 is displaced to the left with respect to the reference position BL as the bottom wall 1b of the chamber 1 expands, but the placing table 2 moves to the right with respect to the bottom wall 1b due to the expansion of the attaching plate 30. This reduces the positional displacement of the placing table 2 to the left with respect to the reference position BL. As described above, the substrate processing apparatus 100 according to the embodiment can suppress the positional displacement of the placing table 2 with respect to the reference position BL. As a result, the substrate processing apparatus 100 can suppress non-uniformity of the processing results of the substrate processing on the substrate W.

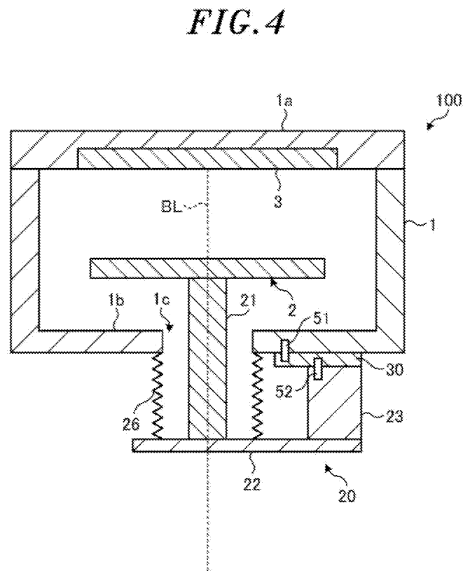

Here, a comparative example will be described. FIG. 4 is a diagram showing an example of a schematic configuration of a substrate processing apparatus 100 according to a comparative example. The substrate processing apparatus 100 according to the comparative example shows the case where the positioning pin 51 and the positioning pin 52 are provided in the same direction with respect to the reference position BL. In FIG. 4, the positioning pin 51 and the positioning pin 52 are provided on the right with respect to the reference position BL.

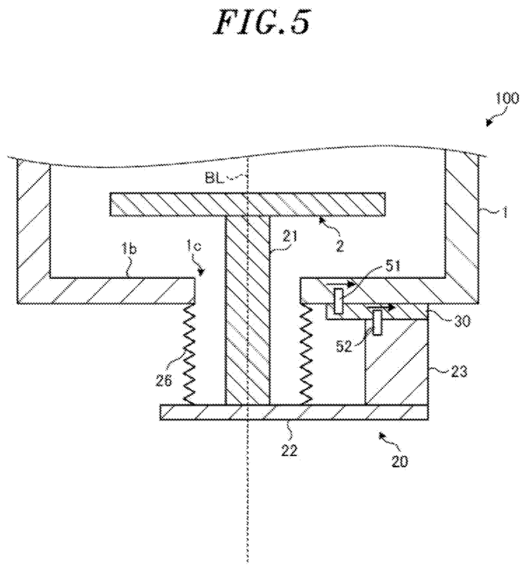

FIG. 5 is a diagram for explaining movement of the attaching plate 30 and the support mechanism 20 of the substrate processing apparatus 100 according to the comparative example. The bottom wall 1b extends by expansion of the chamber 1. For example, the bottom wall 1b of the chamber 1 extends to the right and the left in FIG. 5 with respect to the reference position BL. As a result, the positioning pin 51 in the bottom wall 1b of the chamber 1 moves to the right with respect to the reference position BL. Since the attaching plate 30 is positioned on the bottom wall 1b by the positioning pin 51, the attaching plate 30 moves to the right as a whole. Since the attaching plate 30 is positioned on the bottom wall 1b by the positioning pin 51, it extends to the right by expansion due to heat transfer from the bottom wall 1b. Since the support mechanism 20 is positioned on the attaching plate 30 by the positioning pin 52, it moves to the right as a whole. As a result, in the configuration of the comparative example shown in FIGS. 4 and 5, the positional displacement of the placing table 2 with respect to the reference position BL becomes large.

On the other hand, in the substrate processing apparatus 100 according to the first embodiment shown in FIGS. 1 to 3, the positioning pin 51 and the positioning pin 52 are respectively provided on the opposite sides with respect to the reference position BL, thereby suppressing the positional displacement of the placing table 2 with respect to the reference position BL.

As described above, the substrate processing apparatus 100 according to the first embodiment has the chamber 1 (processing container), the attaching plate 30, and the placing table 2. The attaching plate 30 is attached to the chamber 1 while being positioned by the positioning pin 51 (first positioning mechanism) provided in a direction in which the chamber 1 extends and contracts by expansion and contraction due to temperature change with respect to the predetermined reference position BL serving as the reference for measuring the positional displacement in the chamber 1. The placing table 2 is disposed in the chamber 1 via the support mechanism 20 that is attached to the attaching plate 30 while the support mechanism 20 being positioned by the positioning pin 52 (second positioning mechanism) at a position opposite to the position of the positioning pin 51 with respect to the reference position BL, and the substrate W is placed on the placing table 2. Accordingly, the substrate processing apparatus 100 according to the embodiment can suppress the positional displacement of the placing table 2.

Further, in the substrate processing apparatus 100 according to the first embodiment, the reference position BL, the positioning pin 51, and the positioning pin 52 are arranged in a straight line shape linearly (on a straight line in plan view). Accordingly, the substrate processing apparatus 100 according to the embodiment can suppress the positional displacement of the placing table 2.

Further, the reference position BL is the central position in the chamber 1 along the vertical direction. Accordingly, the substrate processing apparatus 100 according to the embodiment can suppress the positional displacement of the placing table 2 with respect to the central position in the chamber 1. As a result, the substrate processing apparatus 100 according to the embodiment can suppress non-uniformity of the processing results of the substrate processing on the substrate W.

Further, the chamber 1 includes the shower plate 3 for ejecting a gas used for substrate processing above the placing table 2. The reference position BL is set on the central position of the shower plate 3. Therefore, the substrate processing apparatus 100 according to the embodiment can suppress the positional displacement of the placing table 2 with respect to the central position of the shower plate 3. As a result, the substrate processing apparatus 100 according to the embodiment can suppress non-uniformity of the processing results of the substrate processing on the substrate W.

Further, the chamber 1 has the opening 1c formed in the bottom wall 1b. The attaching plate 30 is attached to an outer side of the bottom wall 1b of the chamber 1 while being positioned by the positioning pin 51 so as to surround the opening 1c. The support mechanism 20 includes the support member 21 and the raising and lowering mechanism 23. The support member 21 supports the placing table 2 while penetrating through the opening 1c. The raising and lowering mechanism 23 is attached to the attaching plate 30 while being positioned by the positioning pin 52, and raises and lowers the support member 21. Accordingly, the substrate processing apparatus 100 according to the embodiment can suppress the positional displacement of the placing table 2 while allowing the placing table 2 to be raised and lowered.

### Second Embodiment

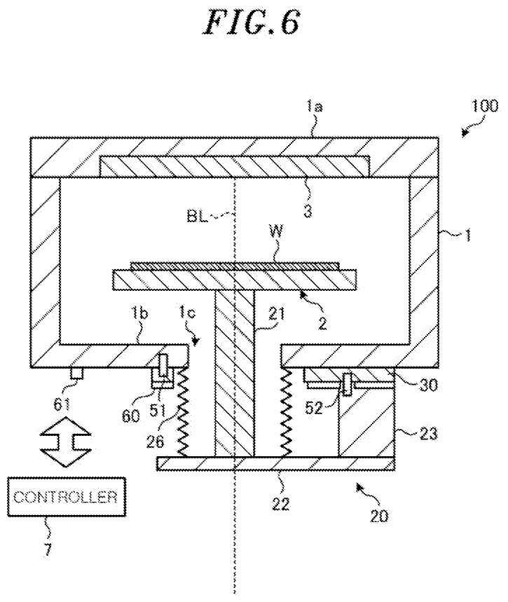

Next, a second embodiment will be described. FIG. 6 is a diagram showing an example of a schematic configuration of a substrate processing apparatus 100 according to the second embodiment. Since the substrate processing apparatus 100 according to the second embodiment has a configuration partially similar to that of the substrate processing apparatus 100 according to the first embodiment shown in FIG. 1, the same parts are denoted by the same reference numerals and description thereof is omitted, and different parts are mainly described.

The substrate processing apparatus 100 is further provided with a temperature control mechanism for adjusting a temperature of the attaching plate 30. For example, the attaching plate 30 is provided with a heater 60. The heater 60 is powered by a heater power supply (not shown) to generate heat. The substrate processing apparatus 100 can adjust the temperature of the attaching plate 30 by being heated by the heater 60. The substrate processing apparatus 100 may allow the temperature of the attaching plate 30 to be adjusted by forming a flow path inside the attaching plate 30 and causing a temperature-controlled temperature control medium to flow through the flow path.

Further, the substrate processing apparatus 100 is further provided with a temperature detector for detecting a temperature of the chamber 1. For example, a temperature sensor 61 is provided on the bottom wall 1b of the chamber 1. The temperature sensor 61 outputs information on the detected temperature to a controller 7.

The substrate processing apparatus 100 has the controller 7. The controller 7 is an information processing device such as a computer. The controller 7 controls each component of the substrate processing apparatus 100. A specific configuration and function of the controller 7 are not particularly limited. The controller 7 has, for example, a main controller, an input device, an output device, a display device, and a storage device. The main controller is, for example, a processor such as a central processing unit (CPU) or a micro processing unit (MPU). The storage device is, for example, any storage device such as a hard disk, an optical disk, or a semiconductor memory device. The storage device stores programs for controlling the substrate processing apparatus 100 and data used in the programs. The main controller reads the programs and the data stored in the storage device, and controls the substrate processing apparatus 100 to perform predetermined processing according to the processing of the programs. The controller 7 controls each component of the substrate processing apparatus 100. For example, the controller 7 can adjust the temperature of the attaching plate 30 by controlling power supplied to the heater 60 from the heater power supply. The controller 7 controls each component of the substrate processing apparatus 100 to perform a method for correcting positional displacement, which will be described later.

The substrate processing apparatus 100 controls expansion and contraction of the attaching plate 30 by controlling the temperature of the attaching plate 30 with the heater 60 so that the positional displacement of the placing table 2 with respect to the reference position BL is reduced. For example, the substrate processing apparatus 100 adjusts the temperature of the attaching plate 30 with the heater 60 such that an amount of expansion/contraction between the reference position BL and a position of the positioning pin 52 in the attaching plate 30 becomes the same as an amount of expansion/contraction between the reference position BL of the bottom wall 1b of the chamber 1 and a position of the positioning pin 51.

For example, the controller 7 controls the temperature of the attaching plate 30 by controlling the power supplied from the heater power supply to the heater 60 according to the temperature of the bottom wall 1b of the chamber 1 detected by the temperature sensor 61. For example, the controller 7 stores a set temperature of the attaching plate 30 for each temperature of the bottom wall 1b of the chamber 1 in the storage device as corresponding information such as table data. The set temperature is the temperature of the attaching plate 30 at which the positional displacement of the placing table 2 with respect to the reference position BL is equal to or less than an allowable value for each temperature of the bottom wall 1b of the chamber 1. For example, the set temperature is the temperature of the attaching plate 30 at which the amount of expansion/contraction between the reference position BL and the position of the positioning pin 52 in the attaching plate 30 is the same as the amount of expansion/contraction between the reference position BL of the bottom wall 1b of the chamber 1 and the position of the positioning pin 51. The controller 7 obtains the set temperature corresponding to the temperature of the bottom wall 1b of the chamber 1 detected by the temperature sensor 61 from the corresponding information stored in the storage device. The controller 7 adjusts the temperature of the attaching plate 30 to the obtained set temperature.

### [Method for Correcting Positional Displacement]

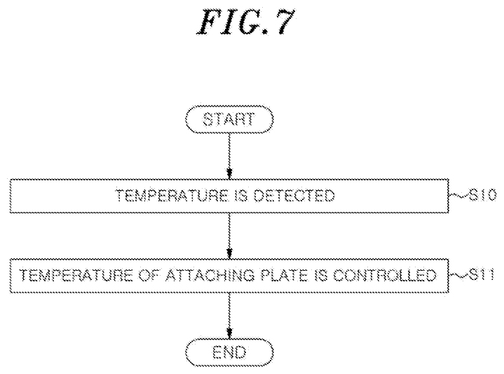

Next, the flow of performing a method for correcting positional displacement according to the embodiment will be described. FIG. 7 is a flowchart showing an example of the flow of the method for correcting positional displacement according to the second embodiment. FIG. 7 shows an example of the flow of performing the method for correcting positional displacement.

The controller 7 detects the temperature of the bottom wall 1b of the chamber 1 by the temperature sensor 61 (step S10).

The controller 7 controls the temperature of the attaching plate 30 by controlling the power supplied from the heater power supply to the heater 60 according to the temperature of the bottom wall 1b of the chamber 1 detected by the temperature sensor 61 (step S11). For example, the controller 7 controls the temperature of the attaching plate 30 based on the detection result of the temperature sensor 61. For example, the controller 7 obtains the set temperature corresponding to the temperature of the bottom wall 1b of the chamber 1 detected by the temperature sensor 61 from the corresponding information stored in the storage device. The controller 7 adjusts the temperature of the attaching plate 30 to the obtained set temperature.

Accordingly, the substrate processing apparatus 100 according to the second embodiment can suppress the positional displacement of the placing table 2 with respect to the reference position BL.

The case where the controller 7 controls the temperature of the attaching plate 30 according to the temperature of the bottom wall 1b of the chamber 1 detected by the temperature sensor 61 has been described as an example. However, the present disclosure is not limited thereto. When the temperature of the bottom wall 1b of the chamber 1 during the substrate processing falls within a certain range, the set temperature of the attaching plate 30 at which the positional displacement of the placing table 2 with respect to the reference position BL becomes an allowable value within the certain range may be set in the controller 7. For example, the set temperature is the temperature of the attaching plate 30 at which the amount of expansion/contraction between the reference position BL and the position of the positioning pin 52 in the attaching plate 30 is the same as the amount of expansion/contraction between the reference position BL of the bottom wall 1b of the chamber 1 and the position of the positioning pin 51. The controller 7 may adjust the temperature of the attaching plate 30 to the set temperature during the substrate processing.

As described above, the substrate processing apparatus 100 according to the second embodiment further has the heater 60 (temperature control mechanism) for adjusting the temperature of the attaching plate 30. The heater 60 adjusts the temperature of the attaching plate 30 so that the amount of expansion/contraction between the reference position BL and the position of the positioning pin 52 in the attaching plate 30 is the same as the amount of expansion/contraction between the reference position BL of the chamber 1 and the position of the positioning pin 51. Accordingly, the substrate processing apparatus 100 according to the embodiment can suppress the positional displacement of the placing table 2.

Further, the substrate processing apparatus 100 according to the second embodiment further has the temperature sensor 61 (temperature detector) for detecting the temperature of the chamber 1 and the controller 7 for controlling the temperature of the heater 60 based on the detection result of the temperature sensor 61. Accordingly, the substrate processing apparatus 100 according to the embodiment can control the expansion and contraction of the attaching plate 30 by adjusting the temperature of the attaching plate 30, thereby suppressing the positional displacement of the placing table 2.

Although the embodiments have been described above, the embodiments disclosed this time should be considered as examples and not restrictive in all respects. Indeed, the above-described embodiments may be embodied in various forms. Further, the above-described embodiments may be omitted, replaced, or modified in various forms without departing from the scope and spirit of the appended claims.

For example, in the above embodiments, the case of suppressing the positional displacement of the placing table 2 with respect to the reference position BL has been described as an example. However, the present disclosure is not limited thereto. The disclosed technique may be applied to suppression of the positional displacement of various components attached to the chamber 1.

Further, in the above embodiments, the case where the placing table 2 can be raised and lowered by the raising and lowering mechanism 23 of the support mechanism 20 has been described as an example. However, the present disclosure is not limited thereto. The support mechanism 20 may be configured to only support the placing table 2 without raising and lowering the placing table 2.

Further, in the above embodiments, the substrate processing apparatus 100 of the present disclosure has been described as an example of a single-chamber type plasma processing apparatus having one chamber. However, the present disclosure is not limited thereto. The substrate processing apparatus 100 of the present disclosure may be a multi-chamber type plasma processing apparatus having a plurality of chambers. Further, the substrate processing apparatus 100 of the present disclosure may be a plasma processing apparatus of a type in which two or more substrates are loaded into two or more chambers and processed simultaneously.

Further, in the above embodiments, the case where the substrate processing is plasma processing such as plasma CVD or plasma etching has been described as an example, but the present disclosure is not limited thereto. The substrate processing may be any processing on a substrate.

Further, in the above embodiments, the case where the substrate W is a semiconductor wafer has been described as an example, but the present disclosure is not limited thereto. The substrate may be any substrate.

What is claimed is:

1. A substrate processing apparatus comprising:
a processing chamber;
an attaching plate attached to the processing chamber while being positioned by a first positioning mechanism in a direction in which the processing chamber extends and contracts due to expansion and contraction caused by temperature changes with respect to a predetermined reference position serving as a reference for measuring positional displacement in the processing chamber; and
a placing table configured to place a substrate thereon and disposed in the processing chamber via a support mechanism attached to the attaching plate, the support mechanism being positioned by a second positioning mechanism at a position opposite to a position of the first positioning mechanism with respect to the reference position.

2. The substrate processing apparatus of claim 1, wherein the reference position, the first positioning mechanism, and the second positioning mechanism are arranged on a straight line.

3. The substrate processing apparatus of claim 1, wherein the reference position is a central position in the processing chamber.

4. The substrate processing apparatus of claim 1, wherein the processing chamber has a shower plate for ejecting a gas used for substrate processing above the placing table, and
the reference position is a central position of the shower plate.

5. The substrate processing apparatus of claim 1, further comprising:
a temperature control mechanism configured to adjust a temperature of the attaching plate.

6. The substrate processing apparatus of claim 5, wherein the temperature control mechanism controls a temperature of the attaching plate such that an amount of extension/contraction between the reference position of the processing chamber and a position of the second positioning mechanism of the attaching plate becomes the same as an amount of extension/contraction between the reference position of the processing chamber and a position of the first positioning mechanism.

7. The substrate processing apparatus of claim 5, further comprising:
a temperature detector configured to detect a temperature of the processing chamber; and
a controller configured to control a temperature of the temperature control mechanism based on a detection result of the temperature detector.

8. The substrate processing apparatus of claim 1, wherein the processing chamber has an opening formed in a bottom wall of the processing chamber,
the attaching plate is attached to an outer side of the bottom wall of the processing chamber to surround the opening, while being positioned by the first positioning mechanism, and
the support mechanism includes:
a support member that penetrates through the opening and supports the placing table; and
a raising and lowering mechanism attached to the attaching plate while being positioned by the second positioning mechanism and configured to raise and lower the support member.

9. A substrate processing apparatus comprising:
a processing chamber;
an attaching member attached to the processing chamber while being positioned by a first positioning mechanism in a direction in which the processing chamber extends and contracts due to expansion and contraction caused by temperature changes with respect to a predetermined reference position serving as a reference for measuring positional displacement in the processing chamber; and
a constituent member attached to the attaching member while being positioned by a second positioning mechanism at a position opposite to a position of the first positioning mechanism with respect to the reference position.

10. A method for correcting positional displacement in a substrate processing apparatus, wherein the substrate processing apparatus includes:
a processing chamber;
an attaching plate attached to the processing chamber while being positioned by a first positioning mechanism in a direction in which the processing chamber extends and contracts due to expansion and contraction caused by temperature changes with respect to a predetermined reference position serving as a reference for measuring positional displacement in the processing chamber;
a placing table configured to place a substrate thereon and disposed in the processing chamber via a support mechanism attached to the attaching plate, the support mechanism being positioned by a second positioning mechanism at a position opposite to a position of the first positioning mechanism with respect to the reference position;
a temperature detector configured to detect a temperature of the processing chamber; and
a temperature control mechanism configured to adjust a temperature of the attaching plate,
the method comprising:
detecting the temperature of the processing chamber by the temperature detector; and
adjusting the temperature of the attaching plate by the temperature control mechanism such that an amount of extension/contraction between the reference position of the processing chamber and a position of the second positioning mechanism becomes the same as an amount of extension/contraction between the reference position of the processing chamber and a position of the first positioning mechanism based on a detection result of the temperature detector.
